(19) United States
(12) Patent Application Publication
(10) Pub. No.: US 2012/0305770 A1
(43) Pub. Date: Dec. 6, 2012

(54) ARTICLE OF APPAREL AND METHOD FOR DISPLAYING A MESSAGE

(76) Inventor: Eduardo MINERA, Brooklyn, NY (US)

(21) Appl. No.: 13/486,233

(22) Filed: Jun. 1, 2012

Related U.S. Application Data
(60) Provisional application No. 61/491,997, filed on Jun. 1, 2011.

(51) Int. Cl. H01L 27/146; B01J 19/12; F21V 21/08; H01L 31/14

(52) U.S. Cl. 250/330; 250/338.1; 250/495.1; 250/206; 362/103

(57) ABSTRACT

An article of apparel such as a necktie, hat, cap, eyeglasses, or a pendant, that has battery-powered infrared (IR) light emitter(s) such as IR-emitting LEDs, in a pattern so that the light emitted when the IR emitters are energized is not visible to the naked eye, yet displays a message that can be electronically seen by an IR detecting and display device, such as a digital camera and smart phone. The arrangement of the IR emitters can form a pattern of a text character, a sign, a mark, an image, or other message, the selection of which can be controlled by a microprocessor.

### CROSS-REFERENCE TO RELATED APPLICATION

This application claims the benefit of U.S. Provisional Patent Application No. 61/491,997, filed on Jun. 1, 2011, the disclosure of which is incorporated herein by reference.

### FIELD OF THE INVENTION

The present invention relates generally to message display systems, more particularly, to display systems that can be worn upon the person and the message is not readily discernible to the naked eye unless an appropriate viewer is utilized.

### BACKGROUND OF THE INVENTION

The use of imaging devices, especially cameras based on CCD (charge-coupled device) technology, in many aspects of daily life appear to be becoming more common. Security cameras, media industry cameras, ATM cameras, personal digital cameras, camcorders, and even cell phone cameras appear to be increasingly available and in use. The use can be widespread and include in the workplace, in public, at sporting or entertainment events, or even in the home. This leads to even more people or organizations capturing images of persons whether they wish to be imaged or not. In addition, these images are more frequently being displayed for possible wide viewing by many other persons either via traditional media broadcast such as TV or by the even more broadly accessible medium of the internet.

Many citizens of this country and of the world consider their individual personal image and likeness to his or her own property, and while it may not be possible to maintain complete privacy in a public venue, they may consider the recording, dissemination, and broadcasting of photos and videos of their image and likeness to be a potential invasion of privacy, and unauthorized use of their image and likeness. A person may desire to display a message that is not visible to the naked eye, such as by other persons that they may encounter through the course of their day, but the message might be imaged by a camera that has the ability to translate the message so that it can then subsequently be viewed by the naked eye.

Specifically the person may wish to display a message, viewable only after imaging by a camera of appropriate capability, such as “Delete” or “Delete Me” to communicate that they want images of them to be deleted. Other potential messages could be for the purpose of advertising, such as the trademark of goods or services. Those around the person would not notice the advertisement but when imaged by a camera that can translate the message then the advertisement would be viewable by any other persons that were shown or accessed the image when it was broadcast or posted.

In addition, the person may not wish to display the message at all times. The person, especially if for advertising purposes, might wish to display the message only for a certain period of time or only while they are at a certain location. Thus it would be useful for this purpose if the message could be turned on or turned off.

There remains a need for displaying a message on the apparel of a person, which is not visible to the naked eye, but which can be viewed after detection by a camera or other infrared capable viewing device. There also remains a need for a device or means for a person who desires to display a message upon their person that is not visible to the naked eye of other persons they may encounter, to display such message to other persons viewing a camera or other infrared capable viewing device.

### SUMMARY OF THE INVENTION

The present invention relates to an article of apparel that includes at least one infrared (IR) light emitter.

The article of apparel can be portable, and can be worn or carried by a person, displayed on an object or article, such as a manikin, or an animal. The article of apparel can include an article of clothing, a clothing accessory, or other apparel accessory, and can include, but not be limited to, bowtie, necktie, vest, scarf, hat, cap, eyeglasses, sunglasses, a pendant, a necklace, a medallion, a button, a boutonniere, a jacket, a coat, a sweater, and a shirt.

The invention also relates to pattern of IR emitters suitable for use in an article of apparel, to be worn on a person, object or article, where the light emitted when the IR emitters are energized is not visible to the naked eye, and displays a message that can be electronically seen by an IR detecting device or including a digital image recording device that detects IR light. The digital image recording device can include a digital camera, video recorder, and the video and camera features on cellular phones, and any other device that can detect, retransmit, and/or record the emitted IR light that is detected. Digital cameras and video recorders that can see IR light can have silicon-based (CCD and CMOS) image sensors that are sensitive to both visible and near infrared (NIR) wavelengths, typically out to about 1200 nm. Many digital camera manufacturers attempt to minimize IR contamination of visible light images by covering the silicon sensors with an internal IR cut filter (IIRCF). Nonetheless, significant IR light reaches the image sensors, which is then displayed on the camera monitor and recorded into the video image.

The pattern of IR emitters comprises an arrangement of a plurality of the IR emitters in a pattern of at least one of a group consisting of a text character, a sign and an image, a message, and a combination thereof.

The IR emitter can include an IR-emitting lamp, and optionally a means for powering the lamp. The IR-emitting lamp includes an IR-emitting light emitting diode (IR-LED). The means for powering can include a battery, a solar panel, other powering means as described herein, and combinations thereof.

The plurality of IR-emitting lamps is electrically connected into a circuit, which includes the powering means. The circuit can also include a control device for controlling the powering on or off the one or plurality of lamps, individually or as a group. The control device can include a mechanical, optical, electronic or other switch for turning power on and off, and/or for pulsing the current through the IR emitters to pulse of the IR light emission. Pulsing can be a regular, rapidly-cycled pulse which will appear to an IR detecting device as a continuous, uninterrupted emission, which can reduce the power drawn by the IR emitters, particularly for IR-LEDs. The pulsing can also be regular or irregular, and sequenced so that the detected IR image itself appears to turn on and off, flicker, etc. The pattern of IR emitters, and in particular IR-LEDs, can be programmed so that subgroups, or even an individual LED, of the pattern are energized and de-energized to emit IR sequentially, orderly, randomly or otherwise. The pulse frequency may be produced using any of a large number of electrical circuit configurations from pulsing integrated circuits (NE555) to relaxation oscillators.

Another aspect of the invention provides that the pattern of IR emitters is an array of IR emitters. The array of IR emitters is provided in an arrangement, which can include rows and columns of LED emitters. The array of emitters can provide for generating numerous types and numbers of images, depending upon which of the IR emitters (identified individually, typically by row and column) are energized. A microprocessor which includes the addresses of each of the IR emitters can be programmed to run one or a plurality of lighting schemes, to display a side variety of IR light patterns. The microprocessor can be accessed by a user via an interface, for example, a mini- or micro-USB port or wirelessly, to install or change the desired images and schemes.

An aspect of the invention can include an article of apparel including a plurality of IR emitters, and can include an IR emitter that emits light only in the NIR range. An aspect of the invention can also include at least one visible light emitter. An aspect of the invention can further include affixing the plurality of IR emitters in the arranged pattern. The article of apparel can include, but is not limited to, a necktie, a bowtie, or a scarf. The pattern according to the invention can include, but is not limited to, a text character, a sign, a message, and a combination thereof.

Another aspect of the present invention is an IR message emitting device that includes at least one IR emitter, a circuitry and a microprocessor controller that energizes at least one IR emitter in response to a user's signal or an external stimulus. The effect is to energize the IR emitters and the user's “message” at the time the user's image is being captured on a digital image recording device. The external stimulus can be an external light signal, including an external IR light beam or signal, or an external visible light flash, including at least one flash of visible light, including a camera flash, or an audible or electronic signal. A photodetector can be configured to detect a flash or beam of such light, and to send a signal to the microprocessor controller to energize the at least one IR emitter. Also includes a method of energizing at least one IR emitter in response to such user's signal or an external stimulus.

Yet another aspect of the present invention is an IR emitting device that includes one or more IR emitters that emit IR light in response to the user's signal or the external stimulus. In this case, the emission of IR light by the IR emitting device is designed or configured to blind or confuse the controls or detecting features of the offending digital image recording device, thereby rendering any image of the user that might be captured out of focus or with a “glow ball” where the IR emitters are positioned.

A further aspect of the invention is a method of delivering an image that cannot be observed directly by the naked eye of a person, such that it is invisible to the naked eye, but can be observed by the naked eye of the person through an IR detecting device, comprising the steps of: a) providing at least one IR emitter arranged in a pattern; b) applying power to the at least one IR emitter to emit IR light in the pattern of the at least one IR emitter; c) detecting the emitted IR light in the pattern; and d) displaying an image of the pattern in an image format that can be observed by the naked eye of the person. The at least one IR emitter can be disposed on an article of apparel. The image format can be a viewing monitor on which the image of the emitted IR light of the pattern is projected. The steps of detecting and displaying can be accomplished with a digital camera including a light detecting element that detects the illumination of the at least one IR light source, and a viewing monitor that displays the image of the pattern for delivering the image for observation directly by the naked eye of the person. The method can further include the step of recording a digital copy of the image of the pattern as the image format.

A further aspect of the invention is a method of emitting a near infrared (NIR) light signal that cannot be observed directly by the naked eye of a person, comprising the steps of: a) providing at least one near infrared (NIR) emitter; b) detecting an external light emission; and c) powering electrically the at least one NIR emitter to emit IR light in response to the detected external light emission. The at least one IR emitter can be disposed on an article of apparel. The at least one NIR emitter can include a plurality of NIR emitters, arranged in a pattern. The external light emission can include at least one flash of visible light, including a light flash from a camera, or an infrared (IR) light signal.

### BRIEF DESCRIPTION OF THE DRAWINGS

The present invention will be understood more fully from the detailed description that follows and from the accompanying drawings, which however, should not be taken to limit the invention to the specific embodiments shown, but are for explanation and understanding only.

FIG. 1 illustrates a necktie according to the present invention having a pattern of infrared (IR) emitters that is arranged to form the message “DELETE”, underlying the outer fabric of a necktie.

FIG. 2 illustrates the electrical circuit of a portion of the pattern of IR emitters of FIG. 1.

FIG. 3 illustrates a person wearing a necktie of the present invention having an energized pattern of the IR emitters according to FIG. 1, as said person would appear to the naked eye of another person, and as said person would appear when viewed using an IR detecting and displaying device.

FIG. 4 illustrates an array of IR emitters under the control of an array microprocessor that energize selected ones of the IR emitters to form an image of a message.

### DETAILED DESCRIPTION OF THE INVENTION

In the following description, specific details are set forth, such as means for wearing a pattern of infrared (IR) emitters on a person, specific types of IR emitters, and camera examples for translating a message from IR emitters for viewing by the naked eye, etc., in order to provide a thorough understanding of the present invention. However, persons having ordinary skill in the relevant arts will appreciate that these specific details may not be needed to practice the present invention.

According to one embodiment of the current invention, the pattern of IR emitters includes IR light emitting diodes (IR-LEDs) that are arranged to form an image, for example, the message “Delete” or “Delete Me”. The pattern is suitable for wear on a person by being located inside the fabric of a necktie. When the necktie containing the pattern of IR emitters is worn by a first person with the pattern non-energized, no IR light is emitted. The message is neither visible to the naked eye of a second person that directly views the first person, nor detectable by an IR-detecting and displaying device. However, when the necktie containing the pattern of IR emitters is worn by a first person and the pattern is energized to emit IR light, the message is not visible to the naked eye of a second person that directly views the first person, but the “Delete Me” message is visible to the naked eye of the second person when viewing the projected image of the first person through the display screen of a camera that is capable of detecting IR light in a field of view, or that can retransmit the field of view, including a visible depiction of the IR light. A digital camera that utilizes a CCD as part of the image capture process is an example of a typically-available camera that can translate the message from IR emitters into a captured image that can be viewed by the naked or unaided eye.

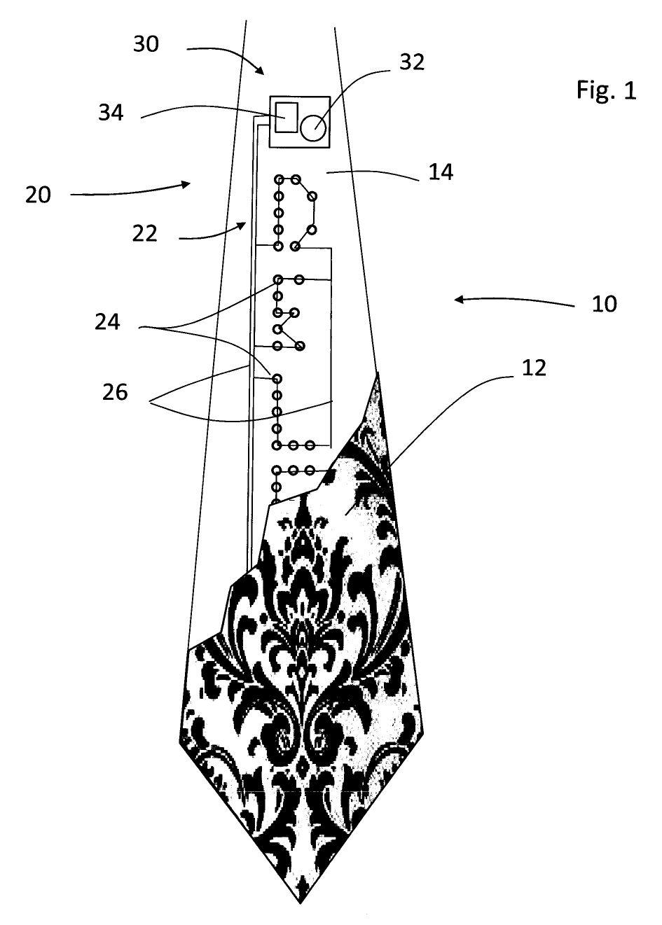

FIG. 1 illustrates an example of an article of apparel shown as a necktie 10 that includes a tie fabric 12, a backing fabric 14, and a device 20 for emitting an IR message. The device 20 includes a pattern 22 of IR-LED emitters 24. The illustrated pattern includes a plurality of IR-LED emitters 24 that do not emit visible light when energized. The IR-LED emitters are an element in an electrical circuit that includes a battery 32 as a power source for energizing the IR-LED emitters 24, a control device 30 including a means 34 for establishing power to the IR-LEDs, and conductors 26 that electrically connect the components of the electrical circuit. The IR emitting device 20 is affixed to the necktie to secure the pattern of IR-LED emitters 24 in place so that the emitted IR light from the device will display the message. The device 20 and its components are preferably not noticeable when looking at the necktie, and are typically positioned on a backing fabric 14 of the tie with an attachment mean (not shown), which can include sewing and adhesive, and underneath the outer tie fabric 12 of the necktie. The outer tie fabric of the necktie is at least partial permeable to IR light so that the IR image of the message can be externally detected and viewed. Most tie fabric is sufficiently light permeable that the emitted IR light shines through the necktie and can be detected and viewed.

The IR-LED emitters 24 are available from numerous sources and in a variety of sizes and operating configurations. A typical IR-LED operates with 1.8 volts and 100 milliamps (mA). The conductors 26 can include copper, aluminum or other suitable electrical conducting wiring. The illustrated power source includes direct current (DC) battery 32, which can range in voltage output from 3 volts to 18 volts, or more. The IR-LED emitters 24 emit light only in the near infrared (NIR) range of about 700 to 1100 nanometers (nm).

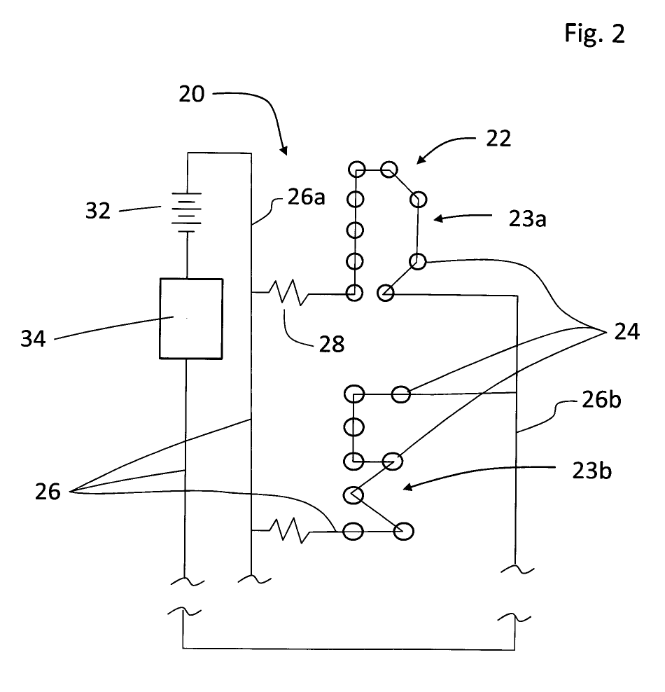

FIG. 2 illustrates a portion of the layout and circuitry of the pattern 22 of IR-LED emitters 24 that is arranged to form the message “DELETE”. The pattern(s) 22 of IR-LED emitters 24 are arranged in one or more subgroups 23a, 23b, etc. that may form a specific portion of a message, include a letter. In the illustrated pattern, subgroup 23a forms the letter “D” and subgroup 23b forms the letter “E”. Each subgroup is wired so that the IR-LEDs 24 within a subgroup is connected in series between a power-side lead line 26a and a drain-side line 26b. In the illustrated pattern 22, the subgroups 23a and 23b are wired in parallel between lines 26a and 26b. Each subgroup is also wired in series between lines 26a and 26b with a resistor 28 that is sized to control the appropriate amount of current and voltage drop through the LEDs to avoid over-powering. The appropriate resistor 28 size will depend upon the circuit layout, number of LEDs and their specification, and the voltage and output of the battery 32. In the illustrated pattern, a 12-volt battery is used with eight IR-LEDs, each IR-LED rated at 100 mA and 1.28 V. The sizing of the resistor 28 follows the calculation:

R=(Vsource−VLEDs)/ALEDs=(12−8×1.28)/0.100=17.6 ohm (1)

The circuit also includes means 34 for communicating power to the IR emitters. This means for communicating power to energize the IR emitters can include a means for turning the electrical power to the IR emitters on and off, or a means for controlling the amount of electrical current, to either dim or brighten the IR emissions from the IR emitters. The power communicating means can include an electrical simple, including but not limited to a push-button switch, a toggle switch, or other switch device transmits electrical power through the switch or cuts it off. The power communicating means 34 can also include an electronic switch that communicates the power, or turns it off, in response to a detected user signal or an external stimulus.

In an alternative embodiment, the power communicating means 34 can include an electronic switch that can include a signal detector that receives a signal from the user, or an external signal, and a microprocessor that controls communication of the power in response to the detection of the external signal. The external stimulus can include an audible noise or sound, or an external light signal or an electromagnetic signal. An example of an external light signal is the bright visible light of a camera's flash. The electronic switch can include a microprocessor and a photodetector, the photodetector configured to detect any bright flash of visible light, and the microprocessor energizing the IR emitters in response to detection by the photodetector. The electronic switch can also include programming for automatically turning off or turning down (dimming) the IR emitters after the external stimulus has ended.

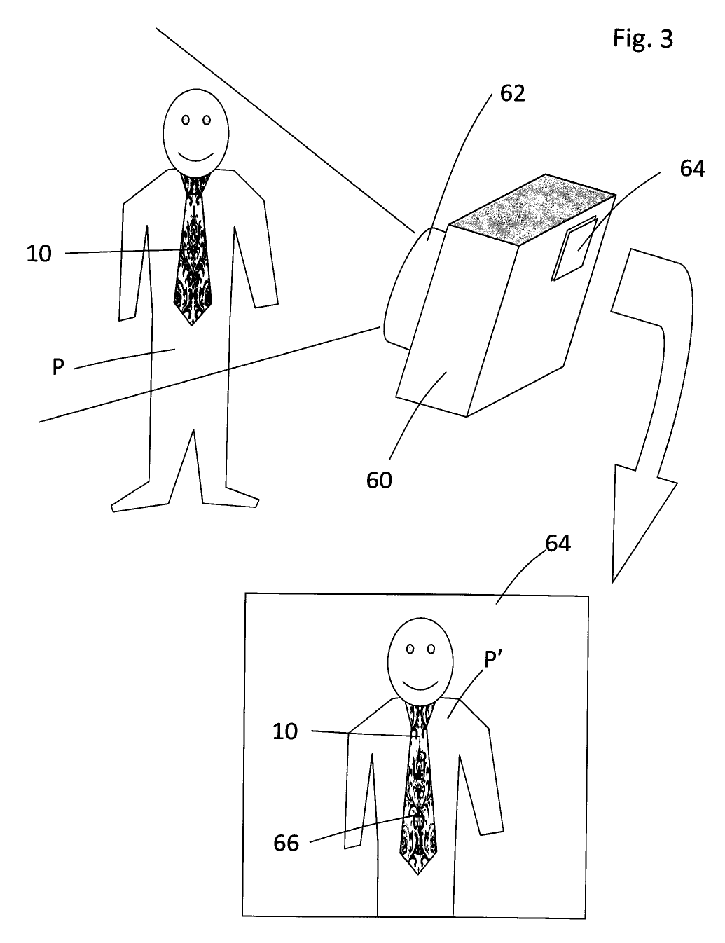

FIG. 3 illustrates how a person P would look to the naked eye when wearing a necktie 10 that includes the IR message emitting device 20 shown in FIGS. 1 and 2 and described herein above. The pattern of IR-LED emitters 24 in the necktie 10 are energized, and IR light is shining through the outer fabric of the necktie 10. To the naked eye, which cannot see IR light, the necktie 10 of person P does not show the message 66 “DELETE”. Further illustrated is a digital camera 60 with an image-capturing lens 62 and internal components (not shown) for detecting the light entering the camera lens. Most commercial and professional digital cameras contain a CCD or CMOS processor which detects both visible light and a portion of the IR light spectrum, and processes a patterned signal commensurate with the detected pattern, as is well known. Detected IR light is therefore processed as a signal that can be displayed on a video monitor 64, typically as a purplish color, and stored or non-volatile or volatile memory. Persons viewing the video monitor 64 with the naked eye can see the detected IR light as a purplish colored light. FIG. 3 illustrates the video monitor 64 of the camera 60, which when viewed by a person with the naked (unaided) eye, will show an image P′ of person P having a necktie 10 that shows the message 66 “DELETE” in a purplish hue. In the same way, digital images and video of the detected images that include the emitted IR message can be recorded to volatile and non-volatile memory, which can be rebroadcasted digitally into digital image files and video files or reproduced into print images. In effect, other persons around person P wearing the necktie will not notice a message 66, but persons viewing a digital photograph, digital broadcast, or digital video monitor of the person P will see the message 66.

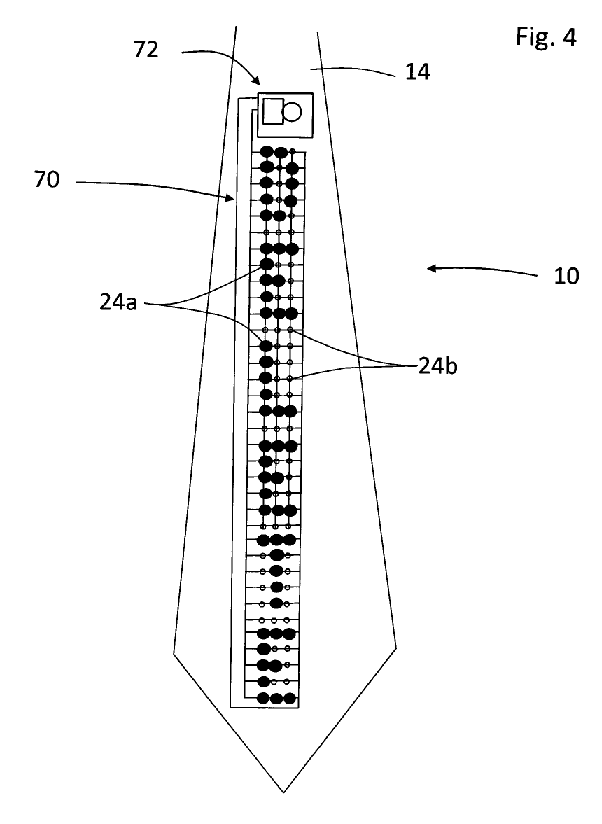

FIG. 4 illustrates another aspect of the invention where the pattern 22 of IR emitters is an array 70 of IR emitters. The device 20 of the article of apparel operates by controlling which ones of the IR-LED emitters 24 are energized under the control of an array microprocessor 72, such as the LED controller model number MCA2X16 from ITS Displays LTD. The array 70 of IR emitters is provided in an arrangement, which can include rows and columns of IR-LED emitters 24. The array 70 of IR emitters can provide for generating numerous types and numbers of images, depending upon which of the IR-LED emitters 24a (identified individually, typically by row and column) are energized, and which ones of the IR-LED emitters 24b are not energized. An array microprocessor 72 which includes the addresses of each of the IR-LED emitters 24 can be programmed to run one or a plurality of lighting schemes, to display a side variety of IR light patterns. The array microprocessor 72 can be accessed by a user via an interface, for example, a mini- or micro-USB port or wirelessly, to install or change the desired images and schemes. FIG. 4 shows an array of IR-LED emitters 24, with selected ones of the IR-LED emitters 24b energized to form a pattern 22 of IR emitters emitting an image under the control of array microprocessor 72.

The present invention can be used for a number of diverse purposes: as a novelty, for advertisement, enforcing or giving notification of privacy, for imbedding a “digital watermark” into digital images, for security, as a passive warning, for educational purposes, for passenger assistance, for protesting passively, and for political speech, to name a few.

The present invention also includes a method of delivering an image that cannot be observed directly by the naked eye of a person, but can be observed by the naked eye of the person through an IR detecting device. The method includes the steps of providing at least one IR emitter, and typically a plurality of IR emitters, arranged in a pattern, which at least one IR emitter can be arranged on the apparel of a person, or on some other object. The method also includes the step of applying power to the at least one IR emitter to illuminate IR light in the pattern of the at least one IR emitter, detecting the IR light illumination, typically with a device such as a digital imaging or video camera, and displaying the pattern in an image format that can be observed by the naked eye of the person. The image format can include a viewing monitor, on the digital camera or separate therefrom, on which the IR light illumination of the pattern is projected. In effect, other persons when looking at the viewing monitor of the camera or at the detected image with a naked or unaided eye, can see the detected IR illumination, which typically appears as a purplish hue. The captured image, including the detected IR light illumination, can be rebroadcasted or recorded in a digital image or video file, and reproduced into a print image, as other versions of the image format.

An IR emitter is not limited to the IR LED, but can include an incandescent IR source, a chemilluminescent IR source, or other suitable IR source. Any available power source in addition to a battery can be used, including a solar panel and/or solar-charged battery, a power grid, a wireless power source, or a separate electronic device, such as a cellular phone, pager, or digital video camera.

The controller or circuitry can also include programming for controlling the energizing of the IR emitters, wherein energizing of the IR emitters can include turning the electrical power to the IR emitters on or off, or controlling the electrical current to either dim or brighten the IR emissions from the IR emitters. The IR message emitting device can include a simple on-off switch, as is well known, or a controller that signals or controls the circuitry of the device to energize in response to a user's signal or an external stimulus. The external stimulus can include an audible noise or an external light signal. An example of an external light signal is the bright light of a camera's flash. The controller 30 can include a microprocessor and a photodetector, the photodetector configured to detect any bright flash of light and send a signal to the microprocessor, which energizes the IR emitters. The controller or circuitry can also include programming for automatically turning off or turning down (dimming) the IR emitters after the external stimulus has ended.

By way of example, many digital cameras, in addition to detecting IR light, may emit an IR signal for the purpose of camera lens focusing. The circuitry of the IR message emitting device includes an IR-sensitive detector that can be configured to emit a signal to energize the pattern of IR emitters, in response to receiving an external beam or emission of IR light, including an IR emission of pre-specified strength or quality. In this situation, the energizing of the IR emitters includes turning on or turning up the electrical power to the IR emitters.

In another aspect of the present invention, the IR-sensitive detector can be configured to emit a signal to energize the pattern of IR emitters, in response to receiving the external beam or emission of IR light from a digital or video camera or smartphone that employs the IR light as an IR signal for focusing of its image. The energizing of the IR emitters can be controlled or programmed to blind or confuse the controls of the camera or smartphone, which can any image generated by the camera or smartphone out of focus or having a “glow ball” where the IR emitters are positioned.

The emitted pattern of IR light can be of any kind, including one or more text characters of any language, numbers, symbols, a sign, an image, a message, a picture, and any combination thereof. The text can include “DELETE ME” and “UNAUTHORIZED IMAGE” to warn persons that the wearer expects privacy of their personal image. Digital and streaming video cameras, and commercial broadcasting cameras can detect and display the IR pattern during televised and public events, giving the opportunity for advertisers to send out their trademark, slogan or other ad image without attracting the attention of the live human participants at the event.

In an alternative embodiment of the invention, the apparel can also include one or more visible light emitters that emit light that can be seen both by the naked eye and through a digital camera. A pattern of visible light emitters can display a visible image of any kind, which in combination with the IR emitters, displays a distinct (and perhaps distinctly different) message to a person viewing the digital monitor or image of the person.

I claim:

1. An article of apparel, including an apparel and a plurality of near-infrared (NIR) emitters.

2. The article of apparel according to claim 1, further including at least one visible light emitter.

3. The article of apparel according to claim 1 wherein the plurality of IR emitters is fixed in an array.

4. The article of apparel according to claim 1 wherein the article is selected from the group consisting of a bowtie, a necktie, a vest, a scarf, a hat, a cap, eyeglasses, sunglasses, a pendant, a necklace, a medallion, a button, a boutonniere, a jacket, a coat, a sweater, and a shirt.

5. The article of apparel according to claim 1, further including a layer of the article of apparel covering a light-emitting surface of the plurality of NIR emitters.

6. The article of apparel according to claim 1, further including a source of electrical current and an on-off switch to control the flow of electrical current to the plurality of NIR emitters.

7. The article of apparel according to claim 1, further including a circuitry, a source of electrical current, and a microprocessor controller that energizes the at least one IR emitter in response to a user's signal or an external stimulus.

8. The article of apparel according to claim 7, wherein the external stimulus is an external light signal.

9. The article of apparel according to claim 8, wherein the external light signal is the light of a camera flash.

10. The article of apparel according to claim 7, wherein the circuitry includes a photodetector, the photodetector configured to detect a flash of light and send a signal to the microprocessor controller to energize the plurality of NIR emitters.

11. The article of apparel according to claim 8, wherein the circuitry further includes an infrared-sensitive detector for receiving an external infrared light signal.

12. The article of apparel according to claim 1 the arranged pattern is a pattern selected from the group consisting of a text character, a sign, a message, and a combination thereof.

13. A method of delivering an image that cannot be observed directly by the naked eye of a person, but can be observed by the naked eye of the person through an infrared (IR) detecting device, comprising the steps of:
a) providing a plurality of IR emitters arranged in a pattern on an article of apparel;
b) applying electrical power to the plurality of IR emitters to emit IR light in the pattern,
c) detecting the emitted IR light in the pattern, and
d) delivering an image of the pattern in an image format that can be observed by the naked eye of the person.

14. The method according to claim 13 wherein the delivering of the image comprises displaying the image in the image format of a projection on a monitor.

15. The method according to claim 13 wherein the delivering of the image comprises recording the image in the image format of a digital image file.

16. The method according to claim 13 further including recording the image in the image format of a digital image file.

17. The method according to claim 13 wherein the steps of detecting and delivering are accomplished with a digital camera including a light detecting element that detects the emitted light of the plurality of IR light sources, and a viewing monitor that displays the image of the pattern for delivering an image of the pattern in an image format that can be observed by the naked eye of the person.

18. The method according to claim 13 wherein the step of providing further includes a providing a photodetector for detecting an external emission of light, and the step of applying power includes detecting the external emission of light, and emitting a control signal to apply the electrical power to the plurality of IR emitters.

19. The method according to claim 18 wherein the external emission of light is an infrared signal.

20. A method of emitting a near infrared (NIR) light signal that cannot be observed directly by the naked eye of a person, comprising the steps of:
a) providing at least one near infrared (NIR) emitter;
b) detecting an external light emission; and
c) powering electrically the at least one NIR emitter to emit IR light in response to the detected external light emission.
